(19) United States
(12) Patent Application Publication
(10) Pub. No.: US 2012/0326898 A1
(43) Pub. Date: Dec. 27, 2012

(54) Coding and Decoding by Means of a Trellis Coded Modulation System

(75) Inventors: Martin Bossert, Ulm (DE); Axel Hof, Unterbohringen (DE); Martin Weckerle, Ulm (DE)

(73) Assignee: Nikia Siemens GmbH & Co., Munich (DE)

(21) Appl. No.: 12/224,496

(22) PCT Filed: Dec. 12, 2006
(86) PCT No.: PCT/EP2006/069580

§ 371 Date: Oct. 1, 2009

(30) Foreign Application Priority Data
Feb. 8, 2006 (EP) 06004038.3

(51) Int. Cl. H03M 5/00

(52) U.S. Cl. 341/52

(57) ABSTRACT

A method codes information, wherein bits that are to be coded are divided into successive first blocks. Second blocks are determined, respectively, by applying a permutation to each of the first blocks. Third blocks are determined by interleaving each of the first blocks with a respective second block. The third blocks are convolution coded, and the bits are combined to form symbols according to the convolutional code. There is a related method for decoding and devices for carrying out the methods.

### CROSS REFERENCE TO RELATED APPLICATIONS

This application is based on and hereby claims priority to PCT Application No. PCT/EP2006/069580 filed on Dec. 12, 2006 and European Application No. 06004038.3 filed on Feb. 28, 2006, the contents of which are hereby incorporated by reference.

### BACKGROUND OF THE INVENTION

The invention relates to a method for coding of information, to a method for decoding of this information, and to apparatuses for carrying out the methods.

Communications systems are used for transmission of information between a transmitter and a receiver. In radio communications systems, information (for example speech, image information, video information, SMS (Short Message Service) or other data) is transmitted with the aid of electromagnetic waves via a radio interface between a transmitter and a receiver. In this case, the electromagnetic waves are emitted at carrier frequencies which are in the frequency band provided for the respective system.

Telecommunications channels, in particular radio channels, are subject to a wide range of interference. Interference resulting from the noise in the receiver, generally additive white Gaussian noise, is unavoidable in all systems. Furthermore, radio channels are subject to many additional types of interference, caused by multipath propagation, scatter, fading, total failures, pulsed interference, interference from other subscribers, and disturbance signals or jamming signals.

When information is being transmitted digitally via a channel, methods are normally used for channel coding in order to ensure reliable transmission which is very largely free of errors. The expression channel coding is a generic term for all coding methods in which the characteristics of a transmission channel are taken into account, in order deliberately to improve the redundancy of data to be transmitted, for error identification and error correction. Channel coding methods are, for example, block coding and convolution coding. In contrast to this, source coding reduces the redundancy. Bits to be coded are converted in the coder at the transmitter end to coded bits, and the coded bits are imaged into symbols which are then transmitted via the channel to the receiver. During transmission, the symbols are generally corrupted by interference influences. The object of the decoder at the receiver end is now to identify any transmission errors which may have occurred, and to determine the transmitted coded bits from the received, corrupted signal.

### SUMMARY

One potential object is to specify an efficient method for coding and for decoding of information. A further aim is to provide apparatuses for carrying out the methods.

The inventors propose a method for coding of information, bits to be coded are split into successive first blocks. Second blocks are determined, to be precise in each case by permutation of a first block. Furthermore, third blocks are determined in that a first block is in each case interleaved with in each case one second block. The third blocks are in each case convolution-coded. After convolution coding, the bits are combined to form symbols.

The information to be coded is in the form of bits which are split into blocks, referred to as “first blocks.” The bits to be coded are preferably completely split into the first blocks, so that each bit is associated with one and only one first block. Second blocks are determined from the first blocks, and there is therefore a relationship between the first and the second blocks. The calculation rule for determination of the second blocks also comprises at least one permutation, that is to say interchanging of the sequence. There are various possible ways for the association of which first block is used for the determination of which second block. However, each first block is preferably used to determine one and only one second block.

Third blocks are determined from the first and the second blocks. The calculation rule for determination of the third blocks comprises at least one interleaving process, as well. This means that contents of a first and of a second block alternate in accordance with a specific pattern in the third blocks. The third blocks are each subjected to convolution coding. A third block is therefore passed to the input of the convolution coder, and the convolution coder emits another block of bits, which is generally longer than the third block that was input. These convolution-coded bits are then combined to form symbols. One symbol is in each case formed from at least two bits. The symbols represent the decoding result and may be sent, for example, to a decoder.

In one refinement, all the first blocks have the same length. In addition, it is advantageous if the second blocks also have this length. With respect to the third blocks, these preferably have twice the length of the first blocks.

In one development, the first blocks each comprise an integer multiple of b-tuples of bits where b is an integer greater than 1, and the second blocks are each determined by reorganization of the sequence of the b-tuples of a first block. If the sequence of the b-tuples is interchanged, the sequence of the bits within the individual b-tuples in this case remains unchanged.

It is particularly advantageous if, during the interleaving process, one first block is in each case interleaved with one second block with the respective second block being determined by permutation from that block which directly follows the respective first block or from that first block which is placed directly before the respective first block. In this way, a third block which has been determined in this way includes contents of a first block, as well as contents of a further first block, which is adjacent to the first-mentioned first block in terms of the sequence of the first blocks.

In a development, the first and the second blocks each comprise an integer multiple of b-tuples of bits where b is an integer greater than 1, and, as a result of the interleaving of a first and of a second block, the determined third block alternately contains in each case one b-tuple of the first block and one b-tuple of the second block. If the b-tuples in the blocks are interleaved, the sequence of the bits within the individual b-tuples in this case remains unchanged.

According to one refinement, per block after the convolution coding and the combination to form symbols, an integer multiple of n-tuples of symbols is produced when n is an integer greater than or equal to 1, and only every second n-tuple is used as a coding result. The n-tuples which are used as the coding result are preferably sent to a decoder. The n-tuples which are not used as a coding result can be rejected. The n-tuples which are used as a coding result preferably correspond to the first blocks.

The inventors also propose a method for decoding of information which has been coded using the method described above. For this an iterative decoding algorithm is used, in which reliability values which have been determined for one block are used for the repeated determination of reliability values of another block. The reliability values are so-called soft-output values of a decoding method. It is possible to determine from them which values were probably available to the coder with respect to specific information items received by the decoder. The statement that reliability values are determined repeatedly for one block means that reliability values for the relevant block have already previously been determined. Repeated determination can improve the result, that is to say the values of the specific reliability values.

In particular, for decoding, reliability values can be determined for a received block, and reliability values for a previously received block are then determined repeatedly using these reliability values. Additionally or alternatively, for decoding, reliability values can be determined for one received block, and reliability values for a block received after this are then determined repeatedly using these reliability values.

It is particularly advantageous for the reliability values to be permutated before they are used for repeated determination of reliability values. This permutation can in particular be matched to the permutation used during the coding process, by being the same as it or corresponding to its reverse process.

In one refinement, for decoding a received block, reliability values are determined for this block 2·w−1 times, where w is an integer greater than 1, with the result of the 2·w−1-th determination being used as the decoding result for this block. The decoding result is used to make the final decision as to which values were probably available to the decoder with respect to specific information items received by the decoder.

The inventors also propose a coding apparatus for the coding of information, which apparatus splits bits to be coded into successive first blocks, determines second blocks in each case by permutation of a first block, determines third blocks in that a first block is in each case interleaved with in each case one second block, applies convolution coding to the third blocks, and combines the bits after the convolution coding to form symbols.

Per first block after the convolution coding and the combination to form symbols, an integer multiple of n-tuples of symbols is produced when n is an integer greater than or equal to 1, and in which the coding apparatus also segregates every second n-tuple, such that only every second n-tuple is used as a coding result.

The decoding apparatus proposed by the inventors receives and decodes information which has been coded using the above coding method and apparatus, determines reliability values for received blocks using an iterative decoding algorithm, in which reliability values which are determined for one block are used for the repeated determination of reliability values of another block.

The proposed apparatuses are particularly suitable for carrying out the proposed methods, and this can also apply to the refinements and developments. The apparatuses may be in the form of a plurality of individual apparatuses which are connected to one another. In particular, it is possible for the coding apparatus and the decoding apparatus to be components of the same overall apparatus.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIG. 1 shows, schematically, a TCM coder,

FIG. 2 shows, schematically, one potential embodiment of a coder proposed by the inventors, and

FIG. 3 shows, schematically, one potential embodiment of a decoder proposed by the inventors.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

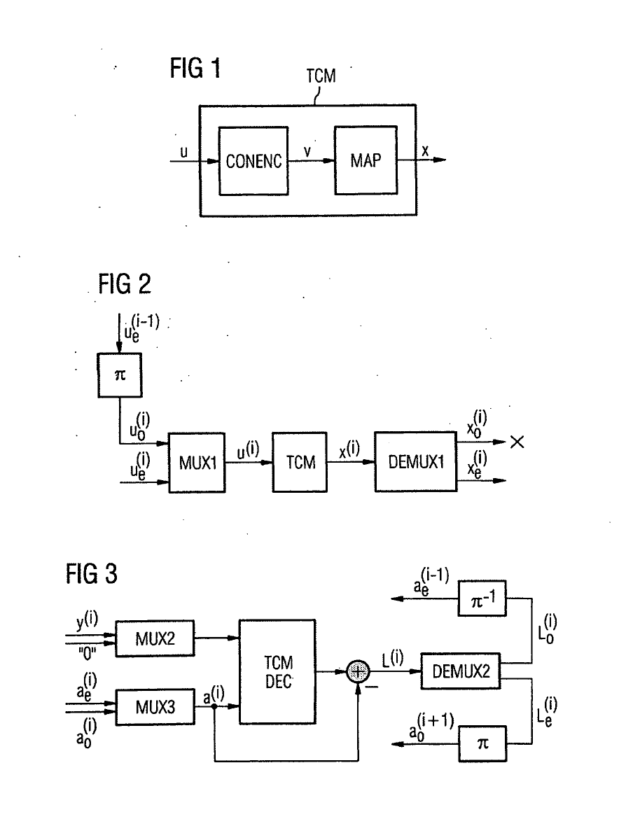

The following embodiment relates to the coding of bits before transmission by radio in a mobile radio communications system. The channel coding adds redundancy to the bits to be coded. This is done in order to reduce the corrupting influences of the radio channel during radio transmission. One example of a method for channel coding is trellis-coded modulation (TCM). FIG. 1 shows a TCM coder TCM, described, for example, in:
G. Ungerboeck: “Channel coding with multilever phase signals”, IEEE Transactions on Information Theory, vol. 28, pp. 55-67, January 1982.

The TCM coder TCM comprises a binary convolution coder CONENC and a mapper MAP in order to map bits onto symbols. The convolution coder CONENC is generally formed by a digital circuit comprising shift registers whose contents are linked in various ways together with the currently arriving bits by addition and modulo-2 operations. u is a block comprising b bits. These b bits are converted by the convolution coder CONENC to the block v, which comprises c bits. The rate of the convolution code is thus b/c. The c-tuple of bits v is fed into the mapper MAP, where q bits are in each case combined to form one symbol. This is based on the assumption that c is an integer multiple of q. The symbol block x that is emitted therefore comprises

$$n = \frac{c}{q}$$

symbols.

One advantage of TCM coding is that it is possible to come closer to the Shannon limit using TCM coding and, for example, in the case of conventional coding with bit-interleaved modulation. This is because TCM coding does not maximize the Hamming distance, but the distance between symbols in Euclidian space.

FIG. 2 shows a proposed coder. In this case, uₑ⁽ⁱ⁾ is a block of N·b bits which is entered into the coder in a time interval i. The time interval i corresponds approximately to the time which the coder requires to process 2·N·b bits. The next block uₑ⁽ⁱ⁺¹⁾ is passed to the coder in the subsequent time interval (i+1). N is an integer, and b is the tuple size as explained above with reference to the TCM coding, and which is processed by the convolution coder of the TCM coder TCM. uₑ⁽ⁱ⁾ therefore contains N b-tuples of bits.

uₒ⁽ⁱ⁾ is also a block of N·b bits which arrives at the coder in the same time interval i as the block uₑ⁽ⁱ⁾. The multiplexer MUX1 arranges the bits in the blocks uₑ⁽ⁱ⁾ and uₒ⁽ⁱ⁾ such that the first b-tuple in the block uₑ⁽ⁱ⁾ occurs first, then the first b-tuple in the block uₒ⁽ⁱ⁾, followed by the second b-tuple in the block uₑ⁽ⁱ⁾, and then the second b-tuple in the block uₑ⁽ⁱ⁾ etc. The sequence of the bits within the b-tuples in the blocks uₑ⁽ⁱ⁾ and uₒ⁽ⁱ⁾ is not changed during this process, and b-tuples in the blocks uₑ⁽ⁱ⁾ and uₒ⁽ⁱ⁾ are simply interleaved in one another in the described manner.

The blocks uₑ⁽ⁱ⁾ are bits which actually have to be coded. In contrast, the bits in the block uₒ⁽ⁱ⁾ are determined from the bits in the block uₑ⁽ⁱ⁻¹⁾ in the predetermined interval (i−1). The permutator π is used for this determination. This changes the sequence of the b-tuples in the block uₑ⁽ⁱ⁻¹⁾, with the sequence of the bits within each b-tuple in the block uₑ⁽ⁱ⁻¹⁾ remaining the same. Therefore, uₒ⁽ⁱ⁾=π(uₑ⁽ⁱ⁻¹⁾) where π( ) means the application of the permutation function to the content of the brackets. The bits in each block uₑ⁽ⁱ⁾ are thus entered in the coder twice: a first time in their original sequence and a second time with a sequence of the b-tuples interchanged by the permutator π.

A block of length N·b comprising exclusively zeros is used for the block uₒ⁽ⁱ⁾ for the first time interval i=1. This may be used as a-priori knowledge in the decoding process, as will be explained later with reference to FIG. 3.

The multiplexer MUX1 emits a block u⁽ⁱ⁾, which comprises 2·N·b bits, because the blocks uₑ⁽ⁱ⁾ and uₒ⁽ⁱ⁾ of length N·b bits have been interleaved in one another by the multiplexer MUX1. Since the block uₒ⁽ⁱ⁺¹⁾ matches the block uₑ⁽ⁱ⁾ except for the sequence of the b-tuples, there is a relationship between the blocks u⁽ⁱ⁾ and u⁽ⁱ⁺¹⁾.

The blocks u⁽ⁱ⁾ are coded by the TCM coder TCM in a manner known per se. The blocks x⁽ⁱ⁾, which each comprise 2·N·n symbols, leave the TCM coder TCM. This is because, as explained with reference to FIG. 1, one symbol block comprising

$$n = \frac{c}{q}$$

symbols leaves the TCM coder TCM per b-tuple of arriving bits. 2·N b-tuples are entered in the TCM coder TCM per time interval i, because the two blocks uₑ⁽ⁱ⁾ and uₒ⁽ⁱ⁾ each comprise N b-tuples.

As already mentioned, the blocks uₑ⁽ⁱ⁾ are the bits to be coded, while the blocks uₒ⁽ⁱ⁾ are simply determined from the bits to be coded and are added thereto by the interleaving in the multiplexer MUX1. Twice as many symbols are therefore produced at the output of the TCM coder TCM as will be present with conventional TCM coding of the blocks uₑ⁽ⁱ⁾. This would lead to the useful data rate being halved. The demultiplexer DEMUX1 is used in order to avoid this. This halves the number of symbols in the blocks x⁽ⁱ⁾ by associating one n-tuple with the block xₑ⁽ⁱ⁾ and one n-tuple with the block xₒ⁽ⁱ⁾, in each case. The block xₑ⁽ⁱ⁾ therefore comprises the first, the third, the fifth, etc. n-tuple of symbols in the block x⁽ⁱ⁾. The block xₒ⁽ⁱ⁾ corresponding comprises the second, the fourth, the sixth etc. n-tuple of symbols in the block x⁽ⁱ⁾. The two blocks xₑ⁽ⁱ⁾ and xₒ⁽ⁱ⁾ each contain N·n symbols.

One block xₑ⁽ⁱ⁾ with N·n symbols is used as a coding result for each block uₑ⁽ⁱ⁾ with N·b bits, and is transmitted to a decoder. Ideal Nyquist pulse forming therefore results in a bandwidth efficiency of

$$η = \frac{b}{n}$$

bits/symbol.

This corresponds to the bandwidth efficiency which will be obtained with conventional TCM coding.

The symbols in the blocks xₒ⁽ⁱ⁾ are rejected, symbolized by a cross, while the symbols in the blocks xₑ⁽ⁱ⁾ are transmitted. The blocks xₑ⁽ⁱ⁾ can be associated directly with the blocks uₑ⁽ⁱ⁾. The actual symbols which are contained in the blocks xₑ⁽ⁱ⁾ depend, however, on the values of the bits in the blocks uₒ⁽ⁱ⁾ because these influence the state of the convolution coder in the TCM coder TCM. Each block uₑ⁽ⁱ⁻¹⁾ therefore influences the coding result xₑ⁽ⁱ⁾ of the respective next block uₑ⁽ⁱ⁾.

FIG. 3 shows the design of a decoder for decoding of the bits which have been coded by a coder as shown in FIG. 2. A block y⁽ⁱ⁾ is received, formed form the superposition of the N·n symbols in a block xₑ⁽ⁱ⁾ with the noise in the radio channel. The received blocks y⁽ⁱ⁾ each having N·n symbols, are interleaved by the multiplexer MUX2 with deletions, symbolized by “0” in FIG. 3. This takes account of the fact that the blocks xₒ⁽ⁱ⁾ have been rejected. The TCM decoder TCM DEC is therefore supplied by the multiplexer MUX2 alternately with an n-tuple of symbols from the block y⁽ⁱ⁾ and an n-tuple of deletions.

Since the decoder has no a-priori knowledge about the blocks uₑ⁽ⁱ⁾ which are sent as blocks xₑ⁽ⁱ⁾ and are received as blocks y⁽ⁱ⁾, the values of the probability matrix aₑ⁽ⁱ⁾ required for TCM decoding are initially set to −b·log 2.

In contrast, a-priori information is available about the blocks uₒ⁽ⁱ⁾, to be precise from the decoding of the previously received block, since the interchanged-sequence version of uₒ⁽ⁱ⁾ was sent as uₑ⁽ⁱ⁻¹⁾, and was received y⁽ⁱ⁻¹⁾. The columns in the matrixes aₑ⁽ⁱ⁾ and aₒ⁽ⁱ⁾ are multiplexed by the multiplexer MUX3. The resulting matrix a⁽ⁱ⁾ is used as a-priori information by the TCM decoder TCM DEC. The TCM decoder TCM DEC calculates soft-output values in the manner known from conventional TCM decoding, that is to say reliability values for the b-tuples of bits contained in u⁽ⁱ⁾, on the basis of the received blocks y⁽ⁱ⁾. The non-binary TCM decoding is described, for example, in:
P. Robertson and T. Woerz: “Bandwidth-efficient turbo trellis-coded modulation using punctured component codes”, IEEE Journal on Selected Areas in Communications, vol. 18, pp. 206-218, February 1998.
H. Ogiwara and M. Yano: “Improvement of Turbo Trellis-Coded Modulation System”, IEICE Trans. Fundamentals, vol. E81-A, no. 10, pp. 2040-2046, October 1998.

The a-priori information a⁽ⁱ⁾ is subtracted from the result of the decoding by the TCM decoder TCM DEC resulting in the 2^{b}×2N matrix L⁽ⁱ⁾ of reliability values. This is split by the demultiplexer DEMUX2 analogously to u⁽ⁱ⁾ and x⁽ⁱ⁾ into the two matrices Lₑ⁽ⁱ⁾ and Lₒ⁽ⁱ⁾ of dimension 2^{b}×N, in that one column of the matrix L⁽ⁱ⁾ is associated with the matrix Lₑ⁽ⁱ⁾ and the next column is associated with the matrix Lₒ⁽ⁱ⁾, alternately.

The described procedure is the first step in an iterative decoding algorithm. The complete method, which comprises a plurality of iteration steps, is carried out as follows: once y⁽ⁱ⁾ has been decoded, the previous block y⁽ⁱ⁻¹⁾ can be decoded again, to be precise using Lₒ⁽ⁱ⁾. In this case, an improved version of aₑ⁽ⁱ⁻¹⁾ is used, to be precise aₑ⁽ⁱ⁻¹⁾=π⁻¹(Lₒ⁽ⁱ⁾). In this case, π⁻¹ corresponds to the reverse operation of the permutation π in FIG. 2. All the previously received blocks y^{(i′)}, where i′<i, can be decoded again in this way, in each case with better a-priori information aₑ^{(i′)}=π⁻¹(Lₒ^{(i′+1)}).

The number of y^{(i′)} which are decoded again corresponds to w−1. This results in a window of size w, where w is an integer greater than 1. When the end of the window is reached, the first block y^{(i-w+1)} in time in the window is decoded. The decoding of y^{(i-w+1)} results in better a-priori information Lₑ^{(i-w+1)}, corresponding to the block uₑ^{(i-w+1)}. This can be used to decode the block y^{(i-w+2)}, to be precise using aₒ^{(i-w+2)}=π(Lₑ^{(i-w+1)}). In this case, π corresponds to the permutation π in FIG. 2. The decoding process is carried out as far as the block y⁽ⁱ⁾ in this way, with L⁽ⁱ⁾ once again being determined using aₒ⁽ⁱ⁾=π(Lₑ⁽ⁱ⁻¹⁾). This completes the iterative decoding method.

In summary, the described iterative decoding method is therefore carried out as follows: the process starts with the decoding of a received block y⁽ⁱ⁾. Starting from these reliability values, the reliability values of the blocks are determined back to the block y^{(i-w+1)}, after which the reliability values of the blocks are determined forwards as far as the block y⁽ⁱ⁾, starting from these reliability values of the block y^{(i-w+1)}.

w=4 is considered as one specific example. It is assumed that the block y⁽⁶⁾ is being decoded for the first time. The previously received blocks y⁽⁵⁾, y⁽⁴⁾ and y⁽³⁾ are then decoded again, in each case using the result of the block with the number incremented by 1. The blocks y⁽⁴⁾, y⁽⁵⁾ and y⁽⁶⁾ are then decoded again, in each case using the result of the block with the number decremented by 1. The reliability values determined most recently for the block y⁽³⁾ are the final decoding result for the block y⁽³⁾. The block y⁽⁷⁾ is now decoded for the first time. The decoding window with the depth w=4 is now shifted by one digit, and the determination process, as explained with reference to the block y⁽⁶⁾, is now carried out with respect to the block y⁽⁷⁾, and the final result for the block y⁽⁴⁾ is determined in this iteration.

Each block y⁽ⁱ⁾ with the exception of the block y⁽¹⁾ is decoded 2w−1 times before the final decoding result is determined. The first block y⁽¹⁾ is decoded only w-times. However, this first block y⁽ⁱ⁾ has the advantage that absolutely reliable a-priori information is available for uₒ⁽ⁱ⁾. As mentioned above, the bits of uₒ⁽¹⁾ are exclusively zeros.

The use of the described iterative decoding algorithm, which is made possible by the coding as described with reference to FIG. 2, allows the bit error rate to be considerably reduced. This reduction increases as the window size w increases. However, the decoding complexity also increases as the window size increases. The reduction in the bit error rate is achieved because there is a relationship between adjacent symbol blocks emitted from the coder. If necessary, this means that a block which is subject to severe noise during transmission can nevertheless still be decoded correctly by the decoder in this way, since the decoding results of blocks received before and after this are included in the decoding of the noisy block.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1. (canceled)

2-17. (canceled)

18. A method for coding of information, comprising:
splitting bits to be coded into successive first blocks;
forming a plurality of second blocks, wherein each second block is determined by applying a permutation to each of the first blocks;
determining a plurality of third blocks by interleaving each of the first blocks with a respective second block; and
convolution coding the third blocks and combining the bits to form symbols.

19. The method as claimed in claim 18, each of the first blocks have a same length.

20. The method as claimed in claim 19, wherein each of the second blocks have the same length as the first blocks.

21. The method as claimed in claim 19, wherein each of the third blocks have twice the length of each of the first blocks.

22. The method as claimed in claim 18, wherein each of the first blocks comprise an integer multiple of b-tuples of bits where b is an integer greater than 1, and
each of the respective second blocks is determined by reorganization of a sequence of the b-tuples of a first block.

23. The method as claimed in claim 18, wherein, during the interleaving process, one first block is interleaved with one respective second block, the respective second block being determined by permutation from a first block that directly follows the respective first block or from a first block that is placed directly before the respective first block.

24. The method as claimed in claim 18, wherein the first and the second blocks each comprise an integer multiple of b-tuples of bits, where b is an integer greater than 1, and, as a result of the interleaving of a first block and a second block, the determined third block alternately contains one b-tuple of the first block and one b-tuple of the second block.

25. The method as claimed in claim 18, wherein, per first block after the convolution coding and the combination to form symbols, an integer multiple of n-tuples of symbols is produced, where n is an integer greater than or equal to 1, and only every second n-tuple is used as a coding result.

26. The method as claimed in claim 25, wherein the n-tuples that are used as coding results correspond to the coded first blocks.

27. A method for decoding of information which has been coded as claimed in claim 18, wherein an iterative decoding algorithm is used, in which reliability values that are determined for one block are used for the repeated determination of reliability values for each of the other blocks.

28. The method as claimed in claim 27, wherein, for decoding, reliability values are determined for a received block, and reliability values for a previously received block are then determined repeatedly using the determined reliability values.

29. The method as claimed in claim 27, wherein, for decoding, reliability values are determined for one received block, and reliability values for a subsequently received block are then determined repeatedly using the determined reliability values.

30. The method as claimed in claim 28, wherein the reliability values are permutated before they are used for the repeated determination of reliability values.

31. The method as claimed in claim 27, wherein, for decoding a received block, reliability values are determined for the received block 2·w−1 times, where w is an integer greater than 1, with the result of the 2·w−1-th determination being used as the decoding result for the received block.

32. A coding apparatus for coding of information, comprising:
means for splitting bits to be coded into successive first blocks;
means for forming a plurality of second blocks, wherein each second block is determined by applying a permutation to each of the first blocks;
means for determining a plurality of third blocks by interleaving each of the first blocks with a respective second block;
means for applying a convolution coding to the third blocks; and
means for combining the bits, after the application of the convolution coding, to form symbols.

33. The coding apparatus as claimed in claim 32, wherein, per first block, after the convolution coding and the combination to form symbols, an integer multiple of n-tuples of symbols is produced, where n is an integer greater than or equal to 1, and
the coding apparatus includes means for segregating every second n-tuple, such that only every second n-tuple is used as a coding result.

34. A decoding apparatus having means for reception and decoding of information that has been coded as claimed in claim 18, further comprising means for determining reliability values for received blocks using an iterative decoding algorithm, in which reliability values that are determined for one block are used for the repeated determination of reliability values of each of the other blocks.
